(19) United States
(12) Patent Application Publication
(10) Pub. No.: US 2026/0354148 A1
(43) Pub. Date: Nov. 5, 2026

(54) SEMICONDUCTOR DEVICE AND METHOD FOR FORMING THE SAME

(71) Applicant: Taiwan Semiconductor Manufacturing Company, Ltd., Hsinchu (TW)

(72) Inventors: Cheng-Hsiang WU, New Taipei City (TW); Shih-Han HUANG, Hsinchu City (TW); Chien-Ying WU, Hsinchu City (TW)

(73) Assignee: Taiwan Semiconductor Manufacturing Company, Ltd., Hsinchu (TW)

(21) Appl. No.: 19/196,541

(22) Filed: May 1, 2025

(51) Int. Cl. H10W 20/42; H10W 20/00; H10W 20/41; H10W 20/43

(52) U.S. Cl. CPC H10W 20/42; H10W 20/075; H10W 20/43; H10W 20/435

(57) ABSTRACT

A semiconductor device is provided. The semiconductor device includes a device substrate, a via formed in the device substrate, a conductive feature partially covering a top surface of the via, and a dielectric layer disposed over the device substrate and extending into the conductive feature, wherein the dielectric layer is in contact with between 5% and 95% of the top surface of the via.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1F show some process steps of forming a semiconductor device, in accordance with some embodiments of the present disclosure.

FIG. 2A is an enlarged view of a region in FIG. 1F, in accordance with some embodiments.

FIG. 2B is a top view of the region, in accordance with some embodiments.

FIG. 2C is enlarged view showing another configuration of the region in FIG. 1F, in accordance with some embodiments.

FIG. 2D is a top view of the structure shown in FIG. 2C, in accordance with some embodiments.

FIG. 2E is enlarged view showing another configuration of the region in FIG. 1F, in accordance with some embodiments.

FIG. 2F is a top view showing one configuration of the structure in FIG. 2E, in accordance with some embodiments.

FIG. 2G is a top view showing another configuration of the structure in FIG. 2E, in accordance with some embodiments.

FIG. 2H is a top view showing another configuration of the structure in FIG. 2E, in accordance with some embodiments.

FIG. 2I is an enlarged view showing another configuration of the region in FIG. 1F.

FIG. 2J is a top view of the structure in FIG. 2I, in accordance with some embodiments.

FIG. 2K is a top view showing another configuration of FIG. 2I, in accordance with other embodiments.

FIG. 2L is a top view showing another configuration of FIG. 2I, in accordance with other embodiments.

FIG. 2M is a top view showing another configuration of FIG. 2I, in accordance with other embodiments.

FIG. 2N is an enlarged view in another embodiment of the region in FIG. 1F, in accordance with some embodiments.

FIG. 2O is a top view showing one configuration of FIG. 2N, in accordance with some embodiments.

FIG. 2P is a top view showing another configuration of FIG. 2N, in accordance with other embodiments.

FIG. 2Q is a top view showing a conductive feature and the via, in accordance with other embodiments.

FIG. 2R is a top view showing a conductive feature and the via, in accordance with other embodiments.

FIG. 2S is a top view showing a conductive feature and the via, in accordance with other embodiments.

FIG. 2T is a top view showing a conductive feature and the via, in accordance with other embodiments.

FIG. 3A to FIG. 3F are schematic view showing process steps following the step in FIG. 1F, in accordance with some embodiments.

FIG. 4A to FIG. 4K are schematic views showing a process of forming a semiconductor device having an etching stop layer over the device substrate, in accordance with some embodiments.

FIG. 5A to FIG. 5I are schematic views showing a process of a forming a semiconductor device, in accordance with some embodiments.

FIG. 6A is a cross-sectional view of a semiconductor device, in accordance with some embodiments.

FIG. 6B is an enlarged view of a region in FIG. 6A, in accordance with some embodiments.

FIG. 6C is an enlarged view showing another configuration of the region in FIG. 6A, in accordance with other embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Use of ordinal terms such as “first”, “second”, etc., in the claims to modify a claim element does not by itself connote any priority, precedence, or order of one claim element over another or the temporal order in which acts of a method are performed, but are used merely as labels to distinguish one claim element having a certain name from another element having the same name (but for use of the ordinal term) to distinguish the claim elements.

The terms “about” and “substantially” typically mean +/−20% of the stated value, more typically +/−10% of the stated value, more typically +/−5% of the stated value, more typically +/−3% of the stated value, more typically +/−2% of the stated value, more typically +/−1% of the stated value and even more typically +/−0.5% of the stated value. The stated value of the present disclosure is an approximate value. When there is no specific description, the stated value includes the meaning of “about” or “substantially”.

Embodiments of the present disclosure provides a semiconductor device having a through-silicon via (TSV) with protrusion suppressing design. Specifically, TSV may expand after the subsequent thermal process. Such expansion may lead to issues, including film delamination or cracking, which in turn may compromise the overall structural integrity and long-term reliability of the device. To mitigate these potential problems, the design includes dielectric material provided over the top surface of the TSV. This dielectric layer functions as an effective thermal barrier to reduce heat transfer through the conductive layer that covers the TSV. The dielectric material helps control the temperature profile of the TSV during thermal processing, thereby minimizing the risk of undesired expansion and subsequent protrusion.

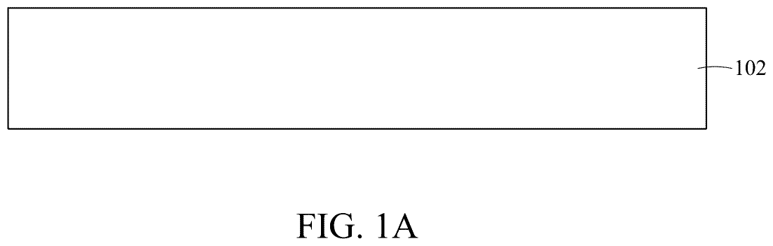

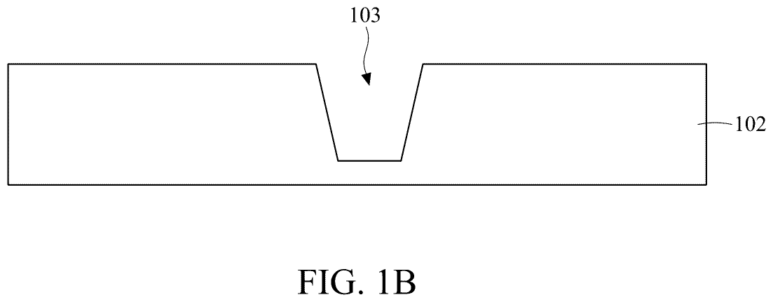

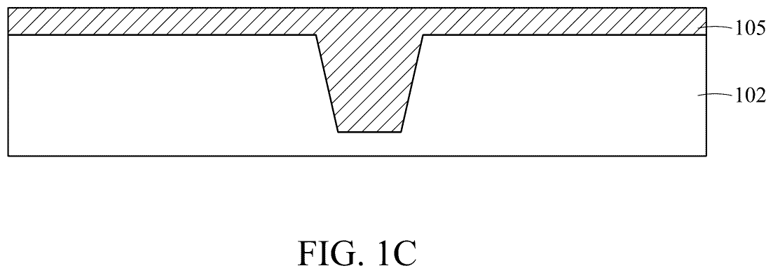

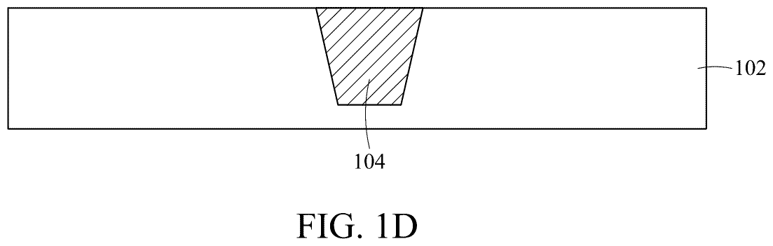

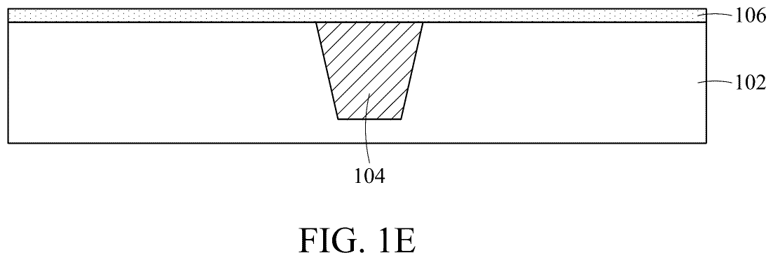

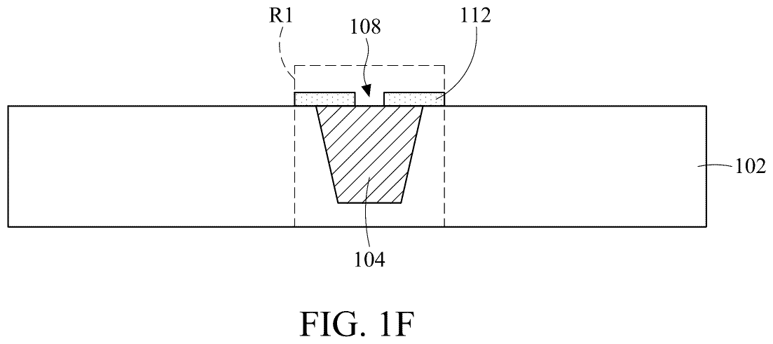

FIG. 1A to FIG. 1F show some process steps of forming a semiconductor device 100, in accordance with some embodiments of the present disclosure. In FIG. 1A, a device substrate 102 is provided, which may include circuitry (not shown) fabricated by front end-of-line (FEOL) processing. For example, the device substrate 102 may include various device components/features, such as a semiconductor substrate, doped wells (e.g., n-wells and/or p-wells), isolation features (e.g., shallow trench isolation (STI) structures and/or other suitable isolation structures), gates (e.g., a gate stack having a gate electrode and a gate dielectric), gate spacers along sidewalls of the gates, source/drains (e.g., epitaxial source/drains), other suitable device components and/or device features, or a combination thereof. In some embodiments, device substrate 102 includes a planar transistor, where a channel of the planar transistor is formed in the semiconductor substrate between respective source/drains and a respective gate is disposed on the channel (e.g., on a portion of the semiconductor substrate in which the channel is formed). In some embodiments, device substrate 102 includes a non-planar transistor having a channel formed in a semiconductor fin that extends from the semiconductor substrate and between respective source/drains on/in the semiconductor fin, where a respective gate is disposed on and wraps the channel of the semiconductor fin (i.e., the non-planar transistor is a fin-like field effect transistor (FinFET)). In some embodiments, device substrate 102 includes a non-planar transistor having channels formed in semiconductor layers suspended over the semiconductor substrate and extending between respective source/drains, where a respective gate is disposed on and at least partially surrounds the channels (i.e., the non-planar transistor is a gate-all-around (GAA) transistor and/or a fork-sheet transistor). The various transistors of device substrate 102 can be configured as planar transistors or non-planar transistors depending on design requirements.

In some embodiments, the device substrate 102 may include various passive electronic devices and active electronic devices, such as resistors, capacitors, inductors, diodes, p-type FETs (PFETs), n-type FETs (NFETs), metal-oxide semiconductor (MOS) FETs (MOSFETs), complementary MOS (CMOS) transistors, bipolar junction transistors (BJTs), laterally diffused MOS (LDMOS) transistors, high voltage transistors, high frequency transistors, other suitable components, or a combination thereof. The various electronic devices can be configured to provide functionally distinct regions of an IC, such as a logic region (i.e., a core region), a memory region, an analog region, a peripheral region (e.g., an input/output (I/O) region), a dummy region, other suitable region, or a combination thereof. The logic region may be configured with standard cells, each of which can provide a logic device and/or a logic function, such as an inverter, an AND gate, an NAND gate, an OR gate, an NOR gate, a NOT gate, an XOR gate, an XNOR gate, other suitable logic device, or a combination thereof. The memory region may be configured with memory cells, each of which can provide a storage device and/or storage function, such as flash memory, non-volatile random-access memory (NVRAM), static random-access memory (SRAM), dynamic random-access memory (DRAM), other volatile memory, other non-volatile memory, other suitable memory, or a combination thereof. In some embodiments, memory cells and/or logic cells include transistors and interconnect structures that combine to provide storage devices/functions and logic devices/functions, respectively, of a chip.

The device substrate 102 may include a bulk semiconductor, a semiconductor-on-insulator (SOI) substrate, or the like, which may be doped (e.g., with a p-type or an n-type dopant) or undoped. The device substrate 102 may include a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or a glass substrate. Other substrates, such as a multi-layered or gradient substrate may also be used. In some embodiments, the semiconductor material of the device substrate 102 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Shallow trench isolation (STI) regions (not separately illustrated) may be formed in the device substrate 102 to isolate active regions in the device substrate 102.

As shown in FIG. 1B, an opening 103 is formed on the device substrate 102 in some embodiments. In some embodiments, forming the opening 103 includes forming a patterned mask layer having an opening exposing a portion of the device substrate 102, and etching the device substrate 102 using the patterned mask layer as an etch mask. The etching may be a dry etching process, a wet etching process, other etching process, or a combination thereof.

In FIG. 1C, a conductive layer 105 is formed over the device substrate 102 and in the opening 103. In some embodiments, the conductive layer 105 includes a metal material, including for example, aluminum, copper, titanium, tantalum, tungsten, ruthenium, cobalt, iridium, palladium, platinum, nickel, tin, gold, silver, other suitable metals, alloys thereof, silicides thereof, or a combination thereof. In some embodiments, the conductive layer 105 includes a bulk metal layer (also referred to as a metal fill layer, a conductive plug, a metal plug, etc.). In some embodiments, the conductive layer 105 includes a barrier layer, an adhesion layer, other suitable layer, or a combination thereof disposed between the bulk metal layer and device substrate 102. The barrier layer can include titanium, titanium alloy (e.g., TiN), tantalum, tantalum alloy (e.g., TaN), other suitable barrier material (e.g., a material that can prevent diffusion of metal constituents from the conductive layer 105 into the device substrate 102). The thickness of the conductive layer 105 may be less than about 20nm, in accordance with some embodiments of the present disclosure.

In some embodiments, the conductive layer 105 may be formed by, for example, using a plating and etching process or through a damascene or dual-damascene process, in which openings are etched into the corresponding dielectric layer (IMD layer) and the openings are filled with a conductive material. The conductive layer 105 may be formed of any suitable conductive material, such as a highly-conductive metal, low-resistive metal, elemental metal, transition metal, or the like. In an embodiment the conductive layer 105 may be formed of copper, although other materials, such as tungsten, aluminum, gold, or the like, could alternatively be utilized. In an embodiment in which the conductive layer 105 is formed of copper, the conductive layer 105 may be deposited by electroplating techniques.

In FIG. 1D, a portion of the conductive layer 105 over the device substrate 102 is removed to expose the device substrate 102, in accordance with some embodiments. Another portion of the conductive layer 105 in the opening 103 forms a via 104. The removal of the conductive layer 105 may be performed by a planarization process, such as chemical mechanical polishing (CMP) or a mechanical grinding process, or may be performed by an isotropic etch process, and/or an anisotropic etch process, in accordance with some embodiments. The via 104 may be formed extending into the device substrate 102 or through the device substrate 102 (i.e. a through-silicon via (TSV)) and may be used to electrically inter-couple features on opposite sides of the semiconductor device 100.

In some embodiments, as shown in FIG. 1E, a conductive layer 106 is formed over the device substrate 102 and the via 104. The material and the forming process of the conductive layer 106 may be similar to that of the conductive layer 105. In FIG. 1F, the conductive layer 106 is patterned to form a conductive feature 112 over the via 104. For example, the conductive layer 106 may be patterned using one or more photolithography processes to form the conductive feature 112, in accordance with some embodiments.

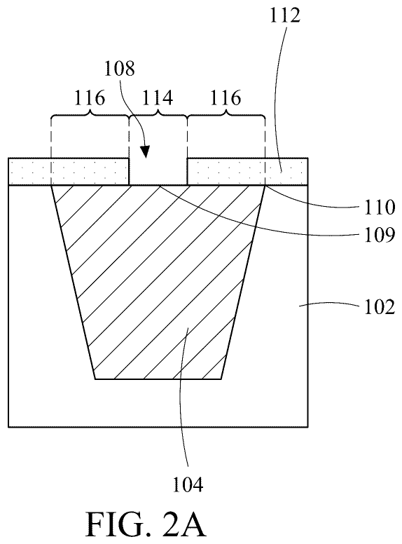

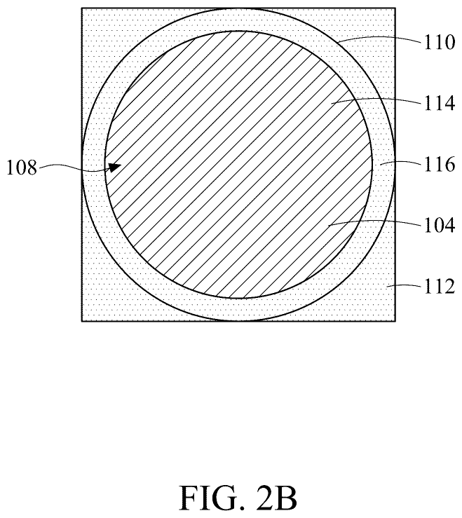

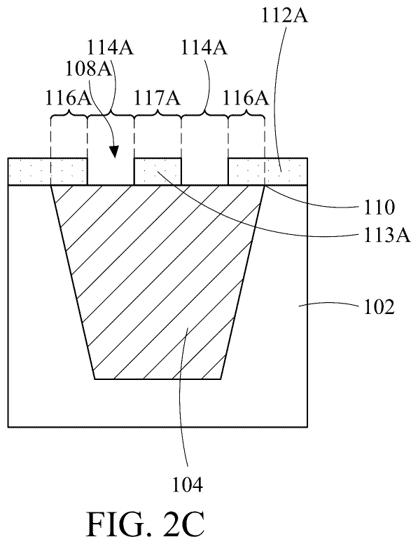

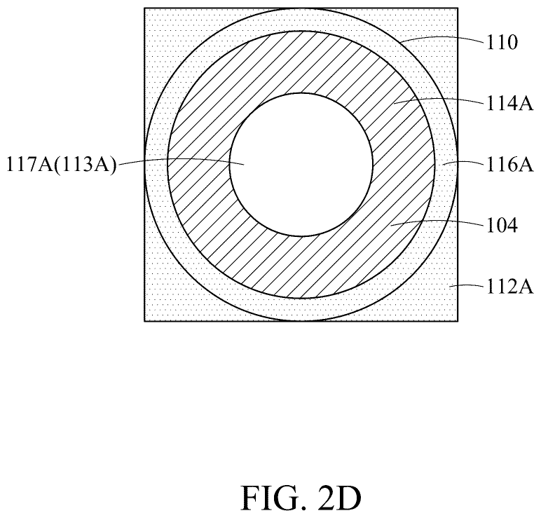

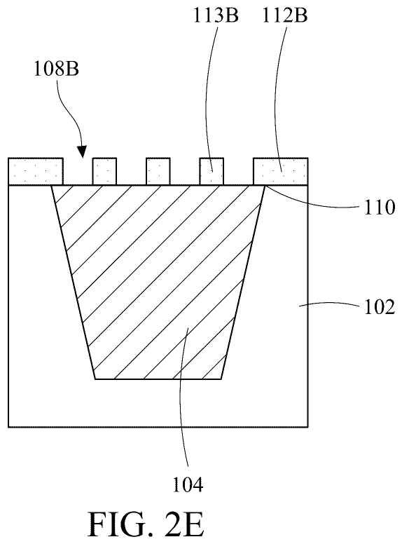

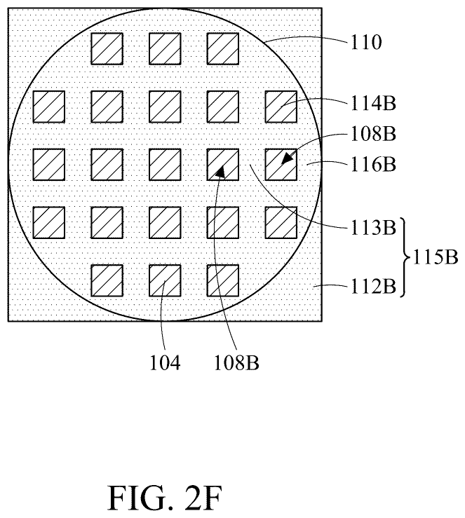

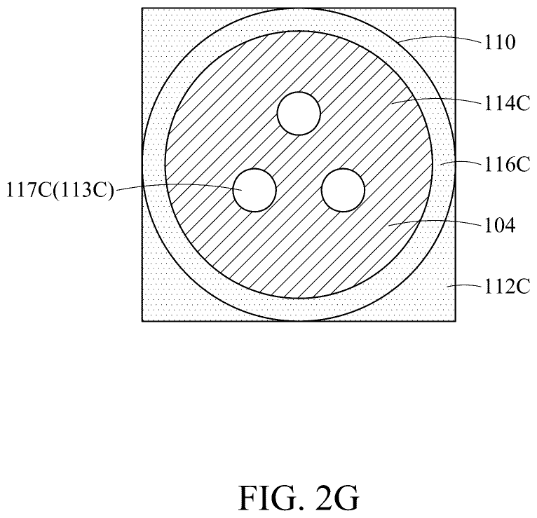

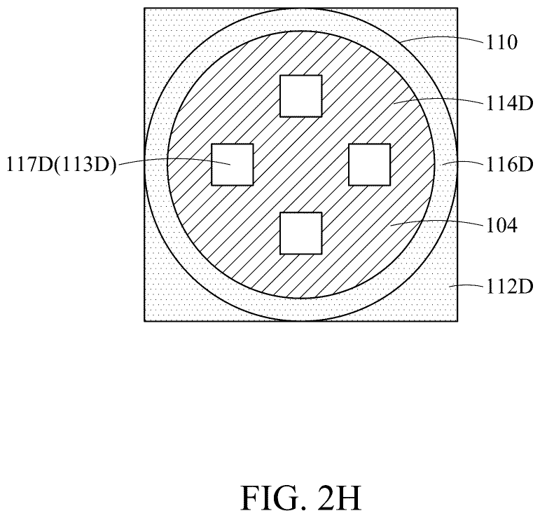

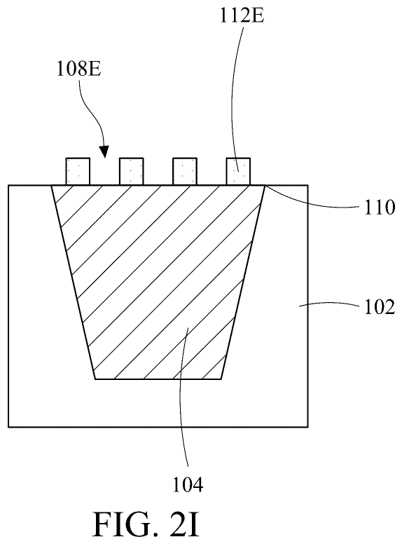

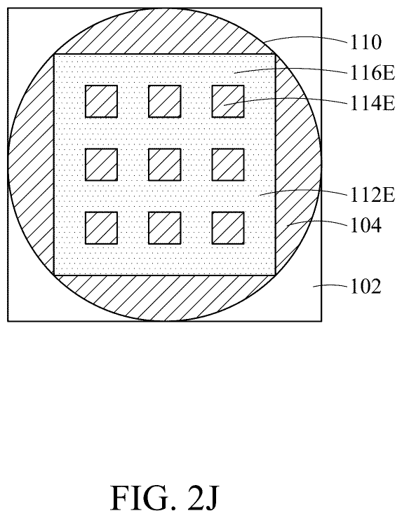

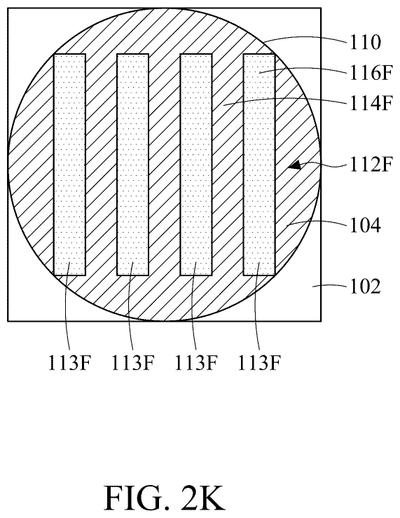

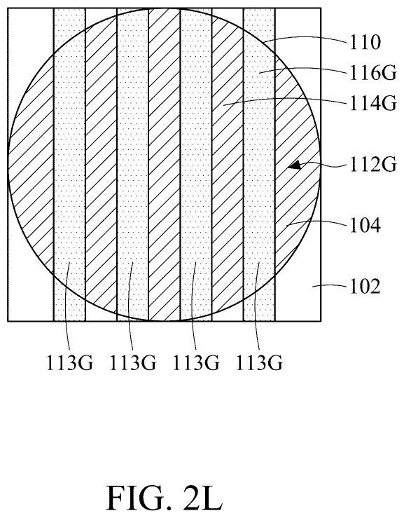

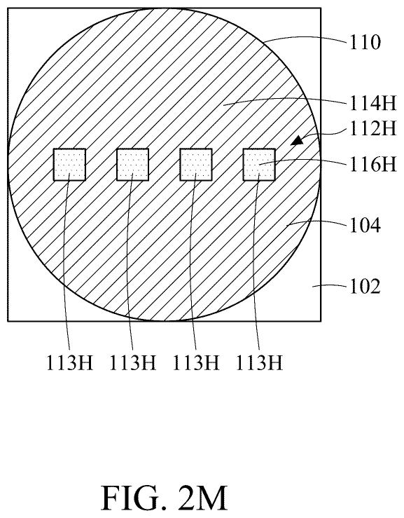

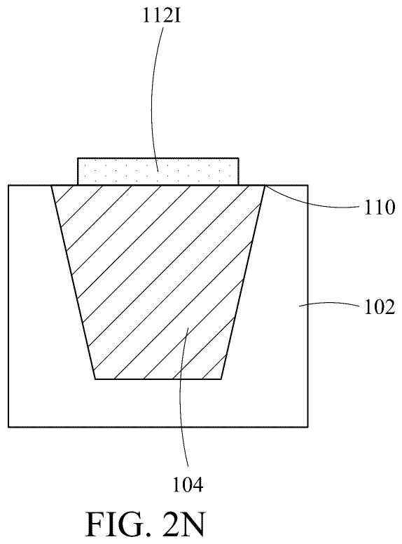

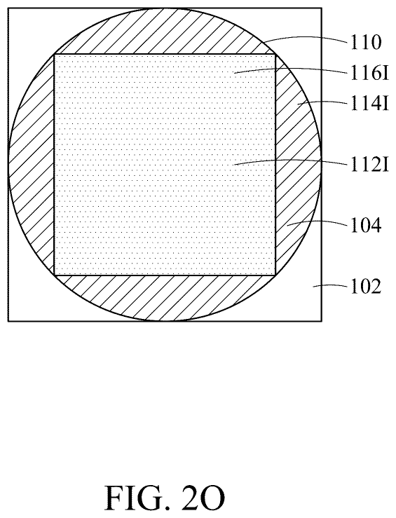

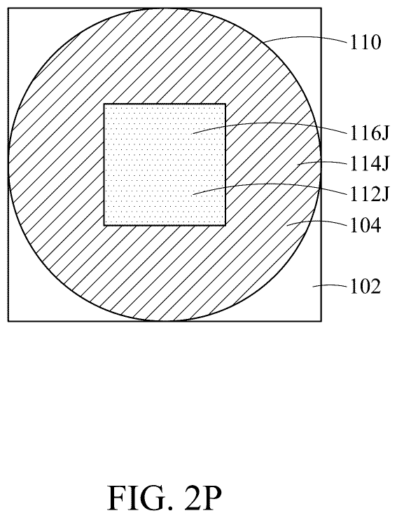

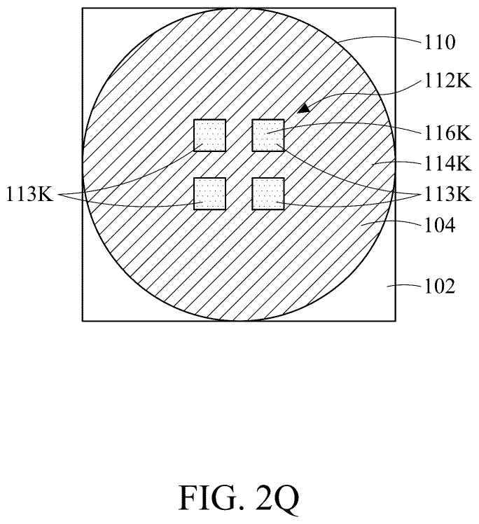

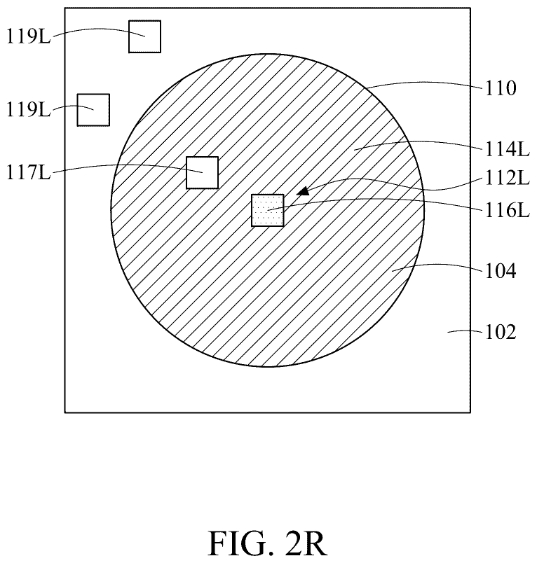

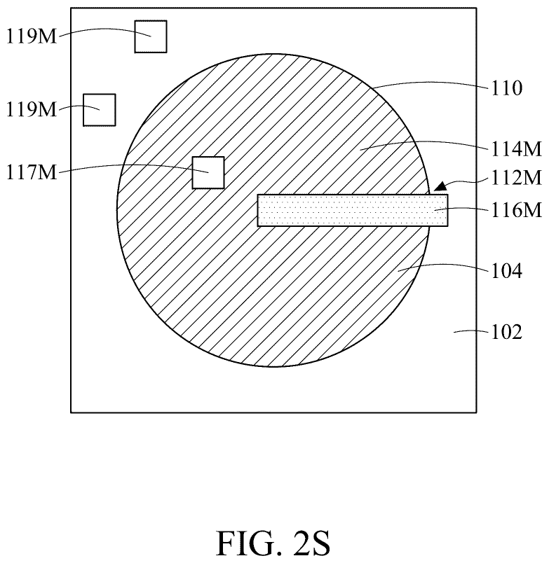

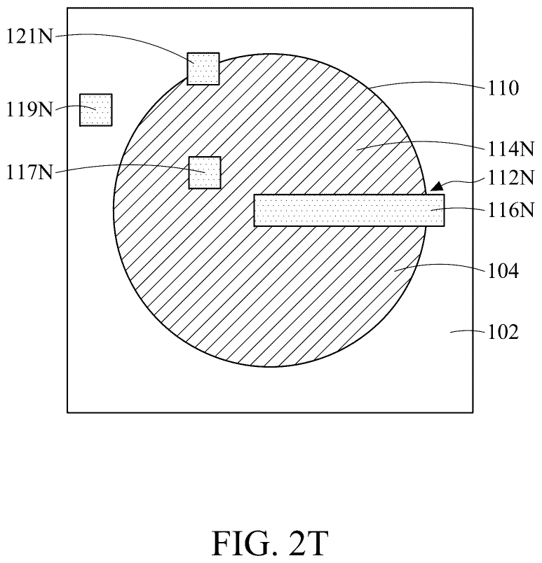

FIG. 2A is an enlarged view of a region R1 in FIG. 1F, and FIG. 2B is a top view of the region R1, in accordance with some embodiments. As shown in FIG. 2A and FIG. 2B, the conductive feature 112 includes an opening 108 over a top surface 109 of the via 104. The area of the via 104 exposed from the opening 108 is defined as a first area 114, and the area of the via 104 that does not overlap the opening 108 and within the edge 110 of the via 104 is defined as a second area 116. In other words, as shown in FIG. 2B, the via 104 is exposed from the opening 108 in the first area 114, and the conductive feature 112 overlaps the via 104 in the second area 116, in accordance with some embodiments of the present disclosure.

When the via 104 undergoes thermal process later, the top surface of the via 104 may protrude due to thermal expansion. Since the via 104 is partially exposed from the opening 108, which means the top surface 109 of the via 104 is not fully covered by the conductive feature 112. By reducing the area of the top surface of the via 104 covered by the conductive feature 112, less heat is directly transferred to via 104 to reduce the thermal expansion, thereby reducing the protrusion level of the via 104. In some embodiments, about 5% to about 95% of the top surface 109 is exposed from the conductive feature 112. Such exposed area will be covered by dielectric material in subsequent steps.

Although FIG. 2A and FIG. 2B show some embodiments of the region R1, the present disclosure is not limited thereto. For example, FIG. 2C is enlarged view showing another configuration of the region R1 in FIG. 1F, and FIG. 2D is a top view of the structure shown in FIG. 2C, in accordance with some embodiments. As shown in FIG. 2C and FIG. 2D, the via 104 is covered by a conductive feature 112A and a feature 113A. The via 104 is exposed from the opening 108A of the conductive feature 112A in a first area 114A, and the conductive feature 112A partially overlaps the via 104 at a second area 116A. The second area 116A may be defined from an edge 110 of the via 104 to an edge of the conductive feature 112A. The feature 113A (e.g. auxiliary feature) overlaps the via 104 at a third area 117A and in contact with the via 104. In some embodiments, the feature 113A may act as a conductive feature to electrically connect with other conductive features disposed thereon, or it may be a dummy feature that does not serve as an electrical connection route but rather contributes to structural uniformity. In some embodiments, the third area 117A is surrounded by the first area 114A, and the first area 114A is surrounded by the second area 116A. In some embodiments of the present disclosure, the conductive feature 112A is in contact with the device substrate 102 at the second area 116A.

FIG. 2E is enlarged view showing another configuration of the region R1 in FIG. 1F, in accordance with some embodiments. As shown in FIG. 2E, the conductive feature 112B may have a plurality of openings 108B, features 113B may be formed over the via 104, and the openings 108B may be formed between the conductive feature 112B and the features 113B. It should be noted that the numbers of the openings 108B may be adjusted based on actual requirement.

The cross-sectional view shown in FIG. 2E may correspond to several types of top views, in accordance with some embodiments. For example, FIG. 2F is a top view showing one configuration of the structure in FIG. 2E, in accordance with some embodiments. As shown in FIG. 2F, the conductive feature 112B may connect to the features 113B, such as the portion of the conductive feature formed between two openings 108B may be defined as the feature 113B. Therefore, the conductive feature 112B and the features 113B may be collectively referred to as a conductive feature 115B, and the conductive feature 115B may have a meshed structure, in accordance with some embodiments. In some embodiments, the via 104 is exposed from the opening 108B of the conductive feature 112B in first areas 114B, and the conductive feature 112B partially overlaps the via 104 at a second area 116B. In some embodiments, the conductive feature 115B extends beyond the edge 110 of the via 104.

FIG. 2G is a top view showing another configuration of the structure in FIG. 2E, in accordance with some embodiments. As shown in FIG. 2G, the features 113C may be mainly used for structural uniformity instead of serving as electrical connectors. In some embodiments, as shown in FIG. 2G, the dummy features 113C may be formed at third areas 117C and may be separated from the conductive feature 112C, and may be separated from each other. In some embodiments, each of the dummy features 113C may have a circular shape. In some embodiments, the conductive feature 112C overlaps the edge 110 of the via 104. In some embodiments, the via 104 is exposed from the conductive feature 112C in a first area 114C, and the conductive feature 112C partially overlaps the via 104 at a second area 116C.

FIG. 2H is a top view showing another configuration of the structure in FIG. 2E, in accordance with some embodiments. As shown in FIG. 2H, the features 113D (e.g. auxiliary features) may be dummy features 113D which are mainly used for structural uniformity instead of serving as electrical connectors. In some embodiments, as shown in FIG. 2H, the features 113D may be separated from the conductive feature 112D, and may be separated from each other. In some embodiments, each of the features 113D may have a rectangular shape. In some embodiments, the conductive feature 112D overlaps the edge 110 of the via 104. In some embodiments, the via 104 is exposed from the conductive feature 112D in a first area 114D, and the conductive feature 112D partially overlaps the via 104 at a second area 116D. The features 113D overlaps the via 104 at a third area 117D, in accordance with some embodiments. In some embodiments, the third area 117D is surrounded by the first area 114D, and the first area 114D is surrounded by the second area 116D.

FIG. 2I is an enlarged view showing another configuration of the region R1 in FIG. 1F. As shown in FIG. 2I, the conductive features 112E may be formed over the via 104, and openings 108E may be formed between the conductive features 112E to expose the via 104. In some embodiments, the edge 110 of the via 104 is fully or partially exposed from the conductive features 112E.

The cross-sectional view shown in FIG. 2I may have different kinds of top views. For example, FIG. 2J is a top view of the structure in FIG. 2I, in accordance with some embodiments. As shown in FIG. 2J, the conductive feature 112E has a meshed structure, and is enclosed in the edge 110 of the via 104 in the top view. In some embodiments, the via 104 is exposed from the conductive feature 112E in a first area 114E, and the conductive feature 112E partially overlaps the via 104 at a second area 116E. In some embodiments, the conductive feature 112E is enclosed within the edge 110 of the via 104 in the top view.

FIG. 2K is a top view showing another configuration of FIG. 2I, in accordance with other embodiments. As shown in FIG. 2K, the conductive feature 112F has a plurality of strip-shaped portions 113F separated from each other. In some embodiments, the strip-shaped portions 113F extend in a substantially identical direction. In some embodiments, lengths of the strip-shaped portions 113F may be identical or different. In some embodiments, the conductive feature 112F is enclosed within the edge 110 of the via 104. In some embodiments, the via 104 is exposed from the conductive feature 112F in a first area 114F, and the conductive feature 112F partially overlaps the via 104 at a second area 116F. In some embodiments, some of the strip-shaped portions 113F may be tangent to the edge 110.

FIG. 2L is a top view showing another configuration of FIG. 2I, in accordance with other embodiments. As shown in FIG. 2L, the conductive feature 112G has a plurality of strip-shaped portions 113G separated from each other. In some embodiments, the strip-shaped portions 113G extend in a substantially identical direction. In some embodiments, lengths of the strip-shaped portions 113G may be identical or different. In some embodiments of the present disclosure, the strip-shaped portions 113G may extend beyond the edge 110 of the via 104. In some embodiments, the via 104 is exposed from the conductive feature 112G in a first area 114G, and the conductive feature 112G partially overlaps the via 104 at a second area 116G. In some embodiments, a length of one of the strip-shaped portions 113G may be identical to a diameter of the via 104 in the top view.

FIG. 2M is a top view showing another configuration of FIG. 2I, in accordance with other embodiments. As shown in FIG. 2M, the conductive feature 112H has a plurality of portions 113H separated from each other. In some embodiments, the portions 113H is enclosed in the edge 110 of the via 104. In some embodiments, the via 104 is exposed from the conductive feature 112H in a first area 114H. In some embodiments, the conductive feature 112H partially overlaps the via 104 at a second area 116H. In some embodiments, the portions 113H are arranged along a straight line in an identical direction.

FIG. 2N is an enlarged view in another embodiment of the region R1 in FIG. 1F, in accordance with some embodiments. As shown in FIG. 2N, a conductive feature 112I may be formed over the via 104. In some embodiments, the edge 110 of the via 104 is fully or partially exposed from the conductive features 112E. In some embodiments, the conductive feature 112I may be formed over a center of the via 104.

The cross-sectional view shown in FIG. 2N may have different kinds of top views. For example, FIG. 2O is a top view showing one configuration of FIG. 2N, in accordance with some embodiments. As shown in FIG. 2O , the conductive feature 112I may have a rectangular shape, the via 104 is exposed from the conductive feature 112I in a first area 114I, and the conductive feature 112I partially overlaps the via 104 at a second area 116I. In some embodiments, corners of the conductive feature 112I having the rectangular shape may be tangent to the edge 110 of the via 104. In some embodiments, the diagonal of the rectangular conductive feature 112I may be identical to the size (e.g. diameter) of the via 104 in the top view.

FIG. 2P is a top view showing another configuration of FIG. 2N, in accordance with other embodiments. As shown in FIG. 2P, the conductive feature 112J may have a rectangular shape, the via 104 is exposed from the conductive feature 112J in a first area 114J, and the conductive feature 112J partially overlaps the via 104 at a second area 116J. In some embodiments, corners of the conductive feature 112J having the rectangular shape may be separated from the edge 110 of the via 104. In some embodiments, in the top view, a diameter of the via 104 may be greater than the maximum size (e.g. diagonal) of the conductive feature 112J having the rectangular shape.

FIG. 2Q is a top view showing a conductive feature 112K and the via 104, in accordance with other embodiments. As shown in FIG. 2Q, the conductive feature 112K may have a plurality of sub-portions 113K, the via 104 is exposed from the conductive feature 112K in a first area 114K, and the conductive feature 112K partially overlaps the via 104 at a second area 116K. In some embodiments, the sub-portions 113K of the conductive feature 112K may be surrounded by the edge 110 of the via 104 in the top view, and the sub-portions 113K do not overlap the edge 110 of the via 104, in accordance with some embodiments.

FIG. 2R is a top view showing a conductive feature 112L and the via 104, in accordance with other embodiments. In some embodiments, the via 104 is exposed from the conductive feature 112L in a first area 114L, and the conductive feature 112L overlaps the via 104 in a second area 116L. In some embodiments, dummy features overlap the via 104 in a third area 117L. In some embodiments, the third area 117L is within the edge 110 of the via 104 in the top view. In some embodiments, dummy features further located over the device substrate 102 in fourth areas 119L and are separated from the via 104. In some embodiments, the fourth areas 119L may be outside the edge 110 of the via 104. In some embodiments, the conductive feature 112L may be electrically connected to the via 104, and the dummy features in the third area 117L or the fourth areas 119L may be electrically isolated from the via 104, or current may not be conducted from the via 104 through the dummy features in the third area 117L or the fourth areas 119L. In some embodiments, the dummy features in the third area 117L or the fourth areas 119L may be used for enhancing structural uniformity.

FIG. 2S is a top view showing a conductive feature 112M and the via 104, in accordance with other embodiments. In some embodiments, the via 104 is exposed from the conductive feature 112M in a first area 114M, and the conductive feature 112M overlaps the via 104 in a second area 116M. In some embodiments, the conductive feature 112M in the second area 116M extends beyond the edge 110 of the via 104. In some embodiments, dummy features overlap the via 104 in a third area 117M. In some embodiments, the third area 117M is within the edge 110 of the via 104 in the top view. In some embodiments, dummy features further located over the device substrate 102 in fourth areas 119M. In some embodiments, the fourth areas 119M may be outside the edge 110 of the via 104. In some embodiments, the conductive feature 112M may be electrically connected to the via 104, and the dummy features in the third area 117M or the fourth areas 119M may be electrically isolated from the via 104, or current may not be conducted from the via 104 through the dummy features in the third area 117M or the fourth areas 119M. In some embodiments, the dummy features in the third area 117M or the fourth areas 119M may be used for enhancing structural uniformity.

FIG. 2T is a top view showing a conductive feature 112N and the via 104, in accordance with other embodiments. In some embodiments, the via 104 is exposed from the conductive feature 112N in a first area 114N, and the conductive feature 112N overlaps the via 104 in a second area 116N. In some embodiments, the conductive feature 112M in the second area 116M extends beyond the edge 110 of the via 104. In some embodiments, dummy features overlap the via 104 in a third area 117N. In some embodiments, the third area 117N is within the edge 110 of the via 104 in the top view. In some embodiments, dummy features further located over the device substrate 102 in a fourth area 119N. In some embodiments, the fourth area 119N may be outside the edge 110 of the via 104. In some embodiments, dummy features further located over the device substrate 102 in a fifth area 121N. In some embodiments, the fifth area 121N may overlap the edge 110 of the via 104. In some embodiments, the conductive feature 112N may be electrically connected to the via 104, and the dummy features in the third area 117N, the fourth area 119N, and the fifth area 121N may be electrically isolated from the via 104, or current may not be conducted from the via 104 through the dummy features in the third area 117N, the fourth area 119N, or the fifth area 121N. In some embodiments, the dummy features in the third area 117N, the fourth areas 119N, and the fifth area 121N may be used for enhancing structural uniformity.

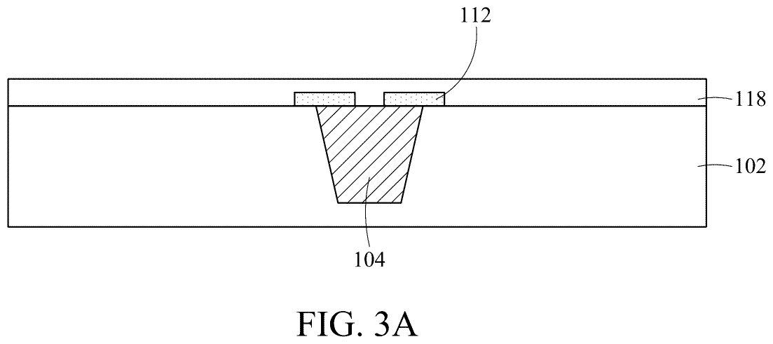

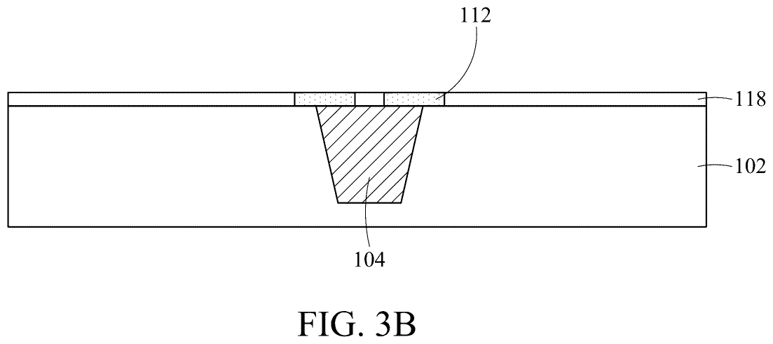

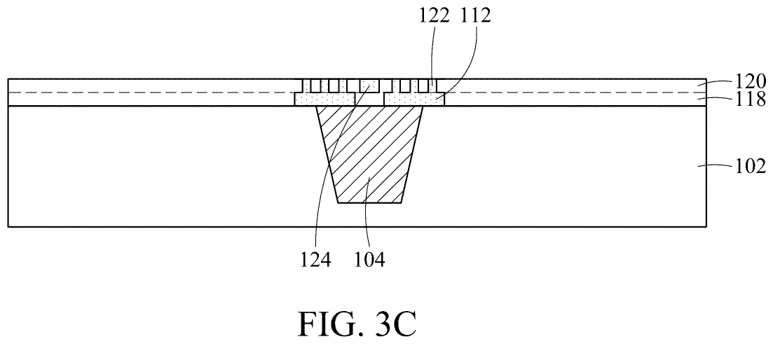

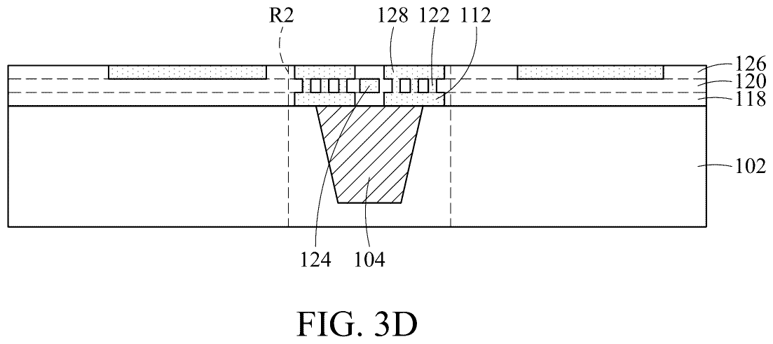

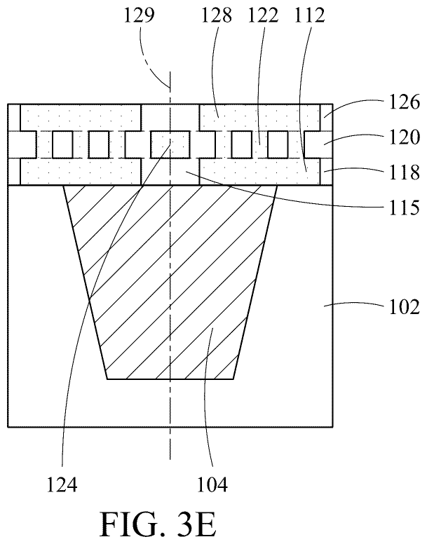

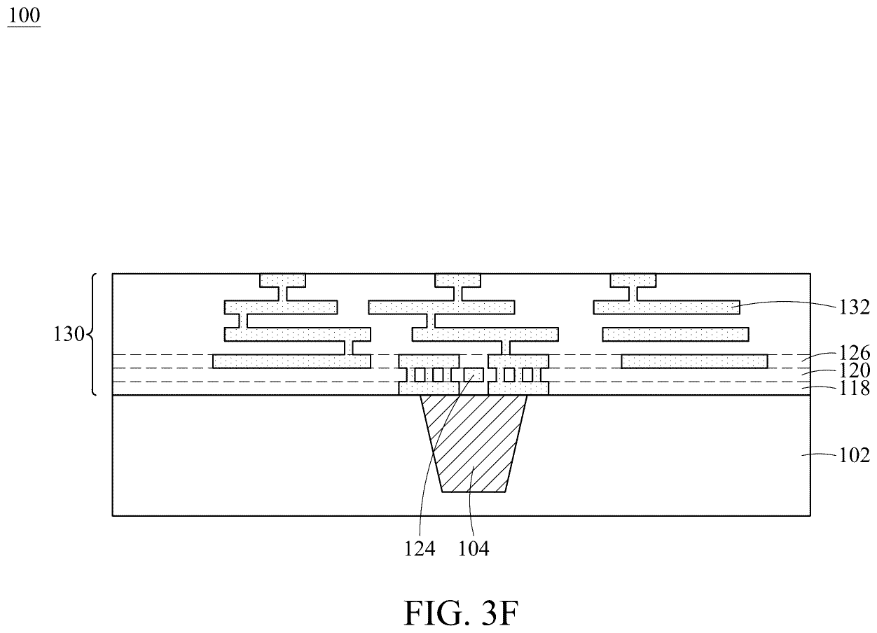

FIG. 3A to FIG. 3F are schematic view showing process steps following the step in FIG. 1F, in accordance with some embodiments. In FIG. 3A, a dielectric layer 118 is formed over the device substrate 102 and covering the via 104 and the conductive feature 112. The opening 108 (or other openings shown in embodiments in FIG. 2A to FIG. 2T) is filled by the dielectric layer 118, so that the top surface of the via 104 is in contact with the dielectric layer 118, which means the dielectric layer 118 extends into the conductive feature 112, thereby reducing the heat transferred through the conductive feature 112 to the via 104 to reduce aforementioned protruding issue of the via 104. In some embodiments, the first area 114 in FIG. 2A is covered by the dielectric layer 118.

In some embodiments, the dielectric layer 118 may be formed by a plasma enhanced CVD (PECVD). In some embodiments, the dielectric layer 118 may be referred to as intermetal dielectric (IMD) layers and may include silicon oxide or a low-k dielectric material whose k-value (dielectric constant) is smaller than that of silicon oxide, which is about 3.9. In some embodiments, the low-k dielectric material includes a porous organosilicate thin film such as SiOCH, tetraethylorthosilicate (TEOS) oxide, undoped silicate glass, doped silicon oxide such as borophosphosilicate glass (BPSG), fused silica glass (FSG), phosphosilicate glass (PSG), fluorine-doped silicon dioxide, carbon-doped silicon dioxide, porous silicon dioxide, porous carbon-doped silicon dioxide, silicon carbon nitride (SiCN), silicon oxycarbide (SiOCN), spin-on silicon based polymeric dielectrics, or combinations thereof.

As shown in FIG. 3B, the dielectric layer 118 is thinned to expose the conductive feature 112 from the dielectric layer 118. The dielectric layer 118 may be thinned by a planarization process, such as chemical mechanical polishing (CMP) or a mechanical grinding process, or may be performed by an isotropic etch process, and/or an anisotropic etch process, in accordance with some embodiments.

In FIG. 3C, conductive features 122 and a feature 124 may be formed over the conductive feature 112 and the dielectric layer 118, respectively. The conductive features 122 and the feature 124 may be formed at a same process, and may be formed by material and process similar to that of the conductive feature 112. Afterwards, a dielectric layer 120 is formed over the dielectric layer 118 and surrounding the conductive feature 122 and the feature 124 by similar material and process of that of the dielectric layer 118 to fill the gaps between the conductive feature 122 and the feature 124. In some embodiments, the feature 124 may be a conductive feature electrically connected to the conductive feature 122 or may be a dummy feature electrically isolated from the conductive feature 122.

In FIG. 3D, conductive features 128 may be formed over the conductive feature 122. The conductive features 128 may be formed by material and process similar to that of the conductive feature 112. Afterwards, a dielectric layer 126 is formed over the dielectric layer 120 and surrounding the conductive features 128 by similar material and process of that of the dielectric layer 118.

FIG. 3E is an enlarged view of a region R2 in FIG. 3D. As shown in FIG. 3E, the dielectric layer 118 formed in the openings shown in FIG. 2A to FIG. 2T may be referred to as a dielectric feature 115, and the feature 124 is formed right over the dielectric feature 115. In some embodiments, a central axis 129 of the via 104 passes through the dielectric feature 115 and the feature 124. In some embodiments, the via 104 may be electrically connected to the conductive features 112, 122 and 128 to transmit electrical signal. In some embodiments, the conductive features 122 and the feature 124 may be collectively electrically connected to each other and form a meshed structure (similar to the conductive feature 115B in FIG. 2F). In some embodiments of the present disclosure, the horizontal size (i.e. the size in a direction parallel to the top surface of the device substrate 102) of the feature 124 may be equal to or greater than that of each of the conductive features 122.

Afterwards, in FIG. 3F, more dielectric layers and conductive features are formed over the dielectric layer 126 to form a dielectric layer 130 and conductive features 132 formed in the dielectric layer 130. The aforementioned dielectric layers 118, 120, and 126 may be included in the dielectric layer 130, and the aforementioned conductive features 112, 122, and 128 may be included in the conductive features 132. The conductive features 132 may include conductive lines, conductive vias, and/or conductive pads. Therefore, a semiconductor device 100 is formed, in accordance with some embodiments.

In some embodiments, the semiconductor device 100 may be a logic die (e.g., central processing units (CPU), a graphics processing unit (GPU), a system-on-chip (SoC), an application processor (AP), a microcontroller, an application-specific integrated circuit (ASIC) die, or the like), a memory die (e.g., a dynamic random access memory (DRAM) die, a static random access memory (SRAM) die, a high bandwidth memory (HBM) die, or the like), a power management die (e.g., a power management integrated circuit (PMIC) die), a radio frequency (RF) die, a sensor die, a micro-electro-mechanical-system (MEMS) die, a signal processing die (e.g., a digital signal processing (DSP) die or the like), a front-end dies (e.g., an analog front-end (AFE) die), the like, or a combination thereof.

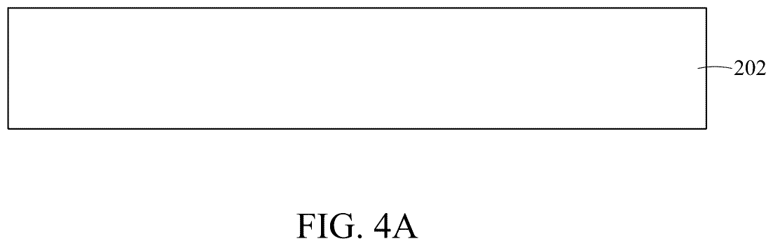

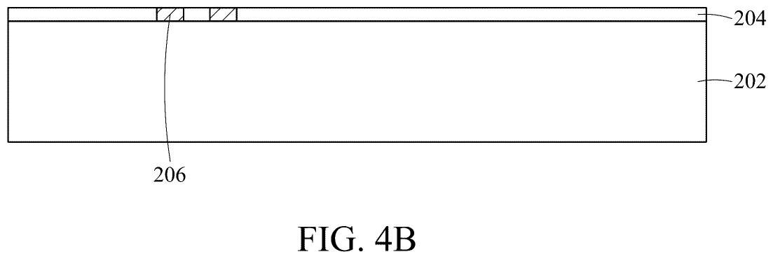

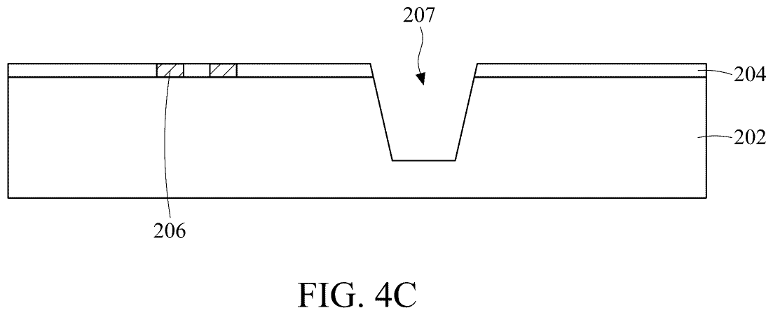

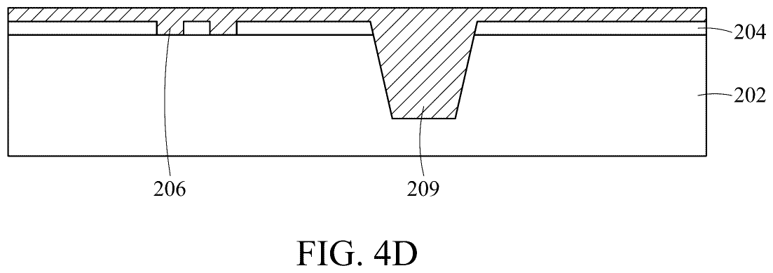

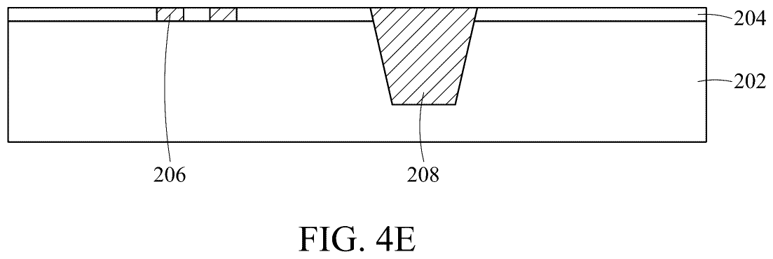

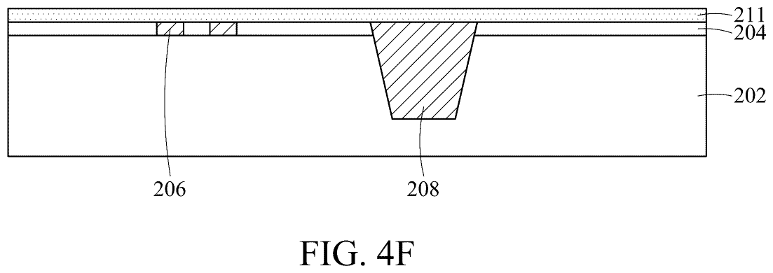

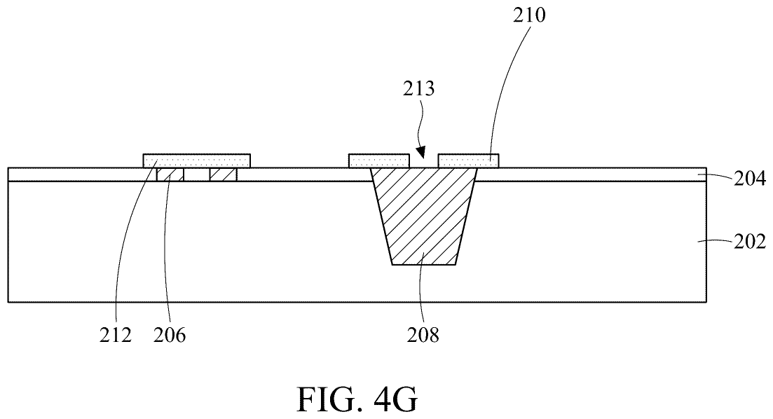

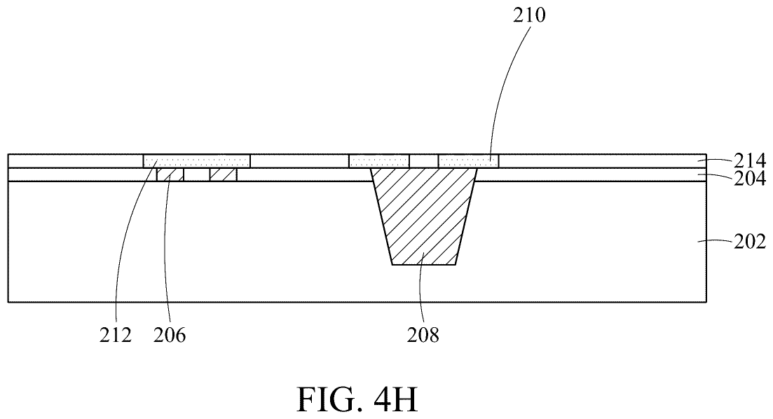

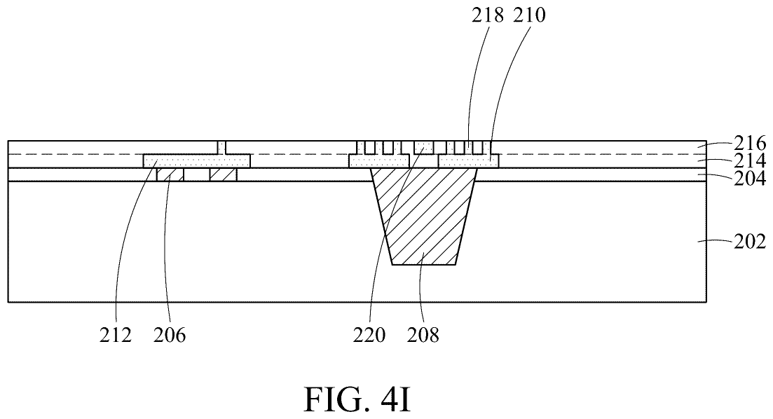

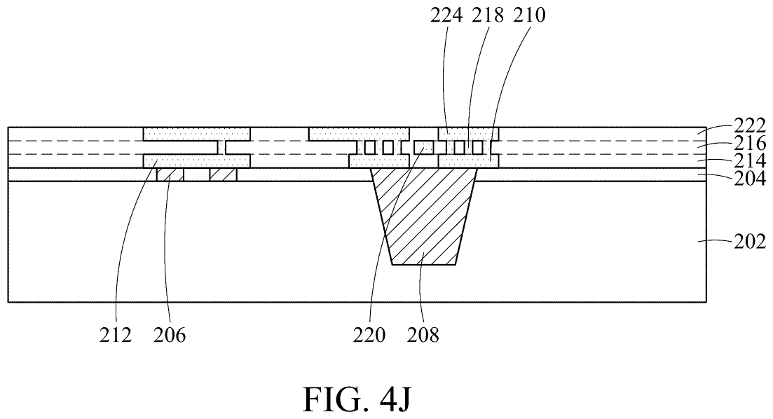

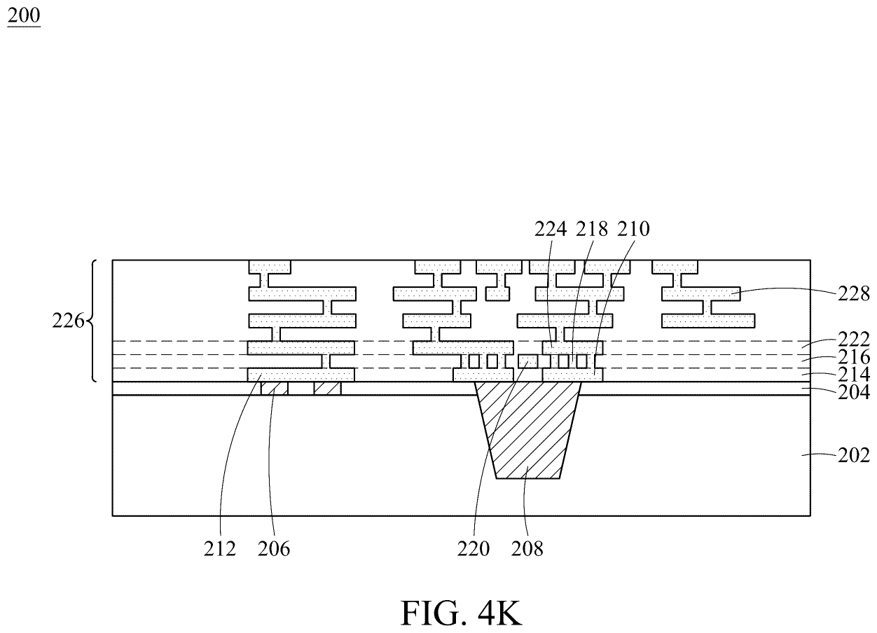

In some embodiments, an etching stop layer may be formed over the device substrate prior forming the via to protect the device substrate. For example, FIG. 4A to FIG. 4K are schematic views showing a process of forming a semiconductor device 200 having an etching stop layer over the device substrate, in accordance with some embodiments. As shown in FIG. 4A, a device substrate 202 is provided in some embodiments. The device substrate 202 may be similar to the device substrate 102, and the details are not repeated again.

Subsequentially, as shown in FIG. 4B, an etch stop layer 204 and a conductive feature 206 are formed over the device substrate 202, in accordance with some embodiments. A material for the etch stop layers is chosen such that etch rates of the etch stop layer 204 may be less then etch rates of corresponding ones of the dielectric layers formed thereon. In some embodiments, the etch stop layer 204 may include one or more layers of dielectric materials. Suitable dielectric materials may include oxides (such as silicon oxide, aluminum oxide, or the like), nitrides (such as SiN, or the like), oxynitrides (such as SiON, or the like), oxycarbides (such as SiOC, or the like), carbonitrides (such as SiCN, or the like), combinations thereof, or the like, and may be formed using spin-on coating, CVD, PECVD, atomic layer deposition (ALD), a combination thereof, or the like. In some embodiments, the conductive feature 206 may be electrically connected to the electronic devices (not shown) formed in the device substrate 202.

As shown in FIG. 4C, an opening 207 is formed in the device substrate 202 and the etch stop layer 204 to penetrate the etch stop layer 204. In some embodiments, forming the opening 207 includes forming a patterned mask layer having an opening exposing a portion of the etch stop layer 204, and etching the etch stop layer 204 and the device substrate 202 using the patterned mask layer as an etch mask. The etching may be a dry etching process, a wet etching process, other etching process, or a combination thereof.

Afterwards, a conductive layer 209 is formed over the etch stop layer 204 and in the opening 207. In some embodiments, the conductive layer 209 includes a metal material, including for example, aluminum, copper, titanium, tantalum, tungsten, ruthenium, cobalt, iridium, palladium, platinum, nickel, tin, gold, silver, other suitable metals, alloys thereof, silicides thereof, or a combination thereof. In some embodiments, the conductive layer 209 includes a bulk metal layer (also referred to as a metal fill layer, a conductive plug, a metal plug, etc.). In some embodiments, the conductive layer 209 includes a barrier layer, an adhesion layer, other suitable layer, or a combination thereof disposed between the bulk metal layer and device substrate 202. The barrier layer can include titanium, titanium alloy (e.g., TiN), tantalum, tantalum alloy (e.g., TaN), other suitable barrier material (e.g., a material that can prevent diffusion of metal constituents from the conductive layer 209 into the device substrate 202.

In some embodiments, the conductive layer 209 may be formed by, for example, using a plating and etching process or through a damascene or dual-damascene process, in which openings are etched into the corresponding dielectric layer (IMD layer) and the openings are filled with a conductive material. The conductive layer 209 may be formed of any suitable conductive material, such as a highly-conductive metal, low-resistive metal, elemental metal, transition metal, or the like. In an embodiment the conductive layer 209 may be formed of copper, although other materials, such as tungsten, aluminum, gold, or the like, could alternatively be utilized. In an embodiment in which the conductive layer 209 is formed of copper, the conductive layer 209 may be deposited by electroplating techniques. The thickness of the conductive layer 209 over the etch stop layer 204 may be between about 20nm to about 500nm, in accordance with some embodiments.

In FIG. 4E, a portion of the conductive layer 209 is removed to expose the etch stop layer 204 and the conductive feature 206. The conductive layer 209 remained in the opening 207 forms a via 208. The removal of the conductive layer 209 may be performed by a planarization process, such as chemical mechanical polishing (CMP) or a mechanical grinding process, or may be performed by an isotropic etch process, and/or an anisotropic etch process, in accordance with some embodiments.

In FIG. 4F, a conductive layer 211 is formed over the etch stop layer 204, the conductive feature 206, and the via 208. The material and forming process of the conductive layer 211 may be similar to that of the conductive layer 209. In some embodiments, as shown in FIG. 4G, the conductive layer 211 is patterned to form a conductive feature 210 over the via 208 and a conductive feature 212 over the conductive feature 206. In some embodiments, an opening 213 is formed in the conductive feature 210 to expose a portion of the via 208 from the opening 213. Since the via 208 is partially exposed from the opening 213, which means the via 208 is not fully covered by the conductive feature 210, in accordance with some embodiments of the present disclosure. By reducing the area of the top surface of the via 208 covered by the conductive feature 210, less heat is directly transferred to via 208 to reduce the thermal expansion, thereby reducing the protrusion level of the via 208, in accordance with some embodiments of the present disclosure.

As shown in FIG. 4H, a dielectric layer 214 is formed over the etch stop layer 204 and the conductive features 206 and 210, and formed in the opening 213, so that the top surface of the via 208 is partially in contact with the dielectric layer 214. Afterwards, the dielectric layer 214 is thinned to expose the conductive features 210 and 212 from the dielectric layer 214. In FIG. 4I, conductive features 218 is formed over the conductive features 210 and 212, a feature 220 is formed over the via 208 and separated from the via 208 by the etch stop layer 204 formed in the opening 213, and then a dielectric layer 216 is formed over the dielectric layer 214 to surround the conductive features 218. In FIG. 4J, conductive features 224 are formed over the conductive features 218, and then a dielectric layer 222 is formed over the dielectric layer 216 to surround the conductive features 224, in accordance with some embodiments. It should be noted that the feature 220 is formed right over the via 208, in accordance with some embodiments of the present disclosure.

In some embodiments, the via 208 may be electrically connected to the conductive features 210, 218 and 224 to transmit electrical signal. In some embodiments, the feature 220 may be a conductive feature or a dummy feature. When the feature 220 is a conductive feature, the via 208 may be electrically connected to the feature 220, in accordance with some embodiments of the present disclosure. When the feature 220 is a dummy feature, the feature 220 may be electrically isolated from the via 208 and may be used for controlling process uniformity, in accordance with some embodiments of the present disclosure.

As shown in FIG. 4K, more dielectric layers and conductive features are formed over the dielectric layer 222 to form a dielectric layer 226 and conductive features 228 formed in the dielectric layer 226. The aforementioned dielectric layers 214, 216, and 222 may be included in the dielectric layer 226, and the aforementioned conductive features 210, 218, and 224 may be included in the conductive features 228, in accordance with some embodiments. The conductive features 228 may include conductive lines, conductive vias, and/or conductive pads. Therefore, a semiconductor device 200 is formed.

In some embodiments, the semiconductor device 200 may be a logic die (e.g., central processing units (CPU), a graphics processing unit (GPU), a system-on-chip (SoC), an application processor (AP), a microcontroller, an application-specific integrated circuit (ASIC) die, or the like), a memory die (e.g., a dynamic random access memory (DRAM) die, a static random access memory (SRAM) die, a high bandwidth memory (HBM) die, or the like), a power management die (e.g., a power management integrated circuit (PMIC) die), a radio frequency (RF) die, a sensor die, a micro-electro-mechanical-system (MEMS) die, a signal processing die (e.g., a digital signal processing (DSP) die or the like), a front-end dies (e.g., an analog front-end (AFE) die), the like, or a combination thereof.

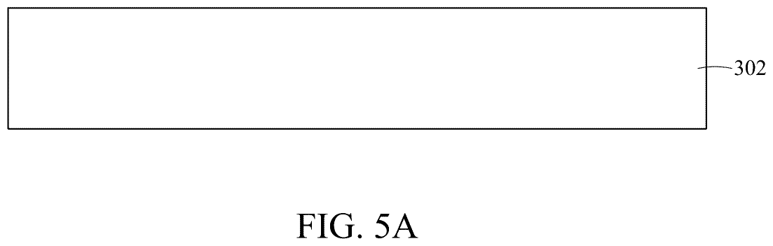

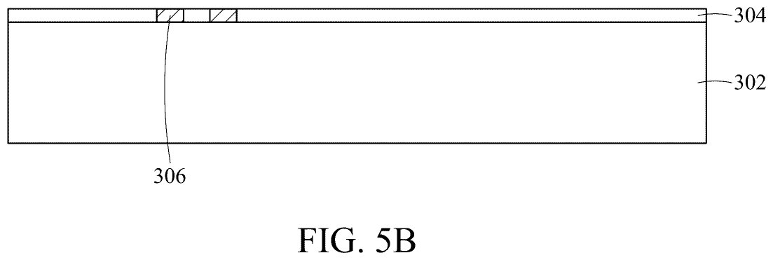

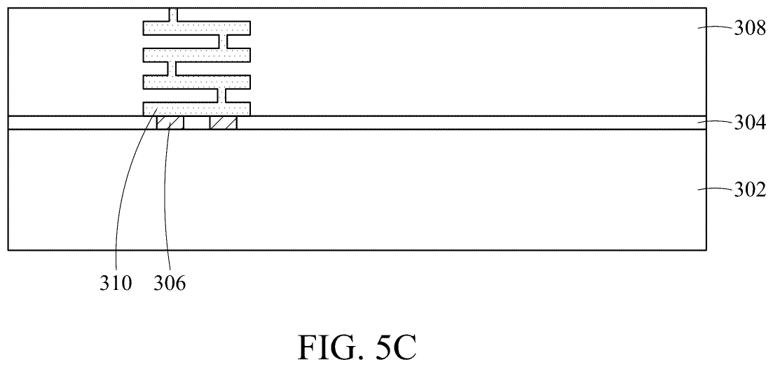

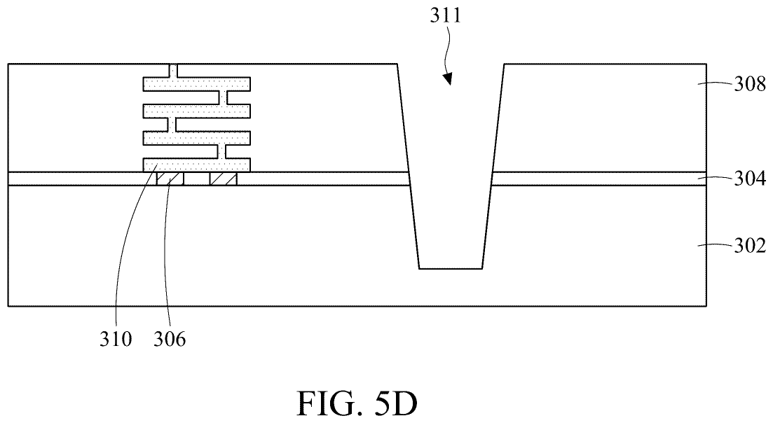

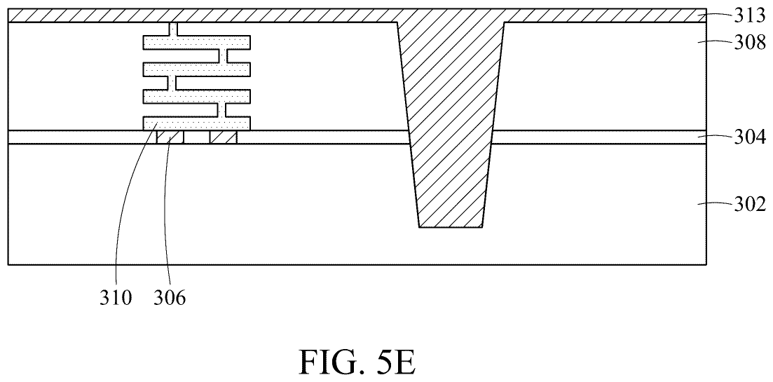

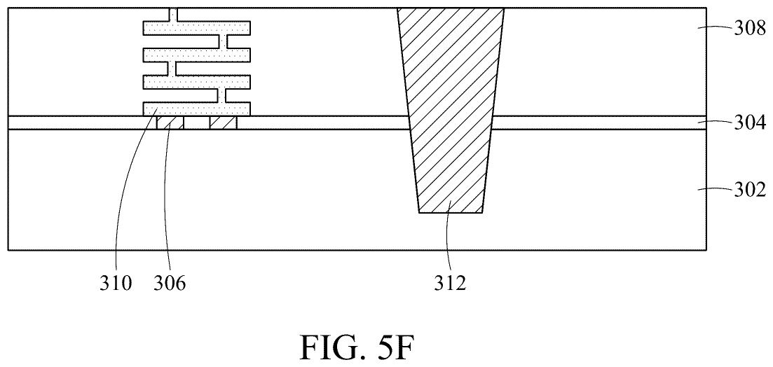

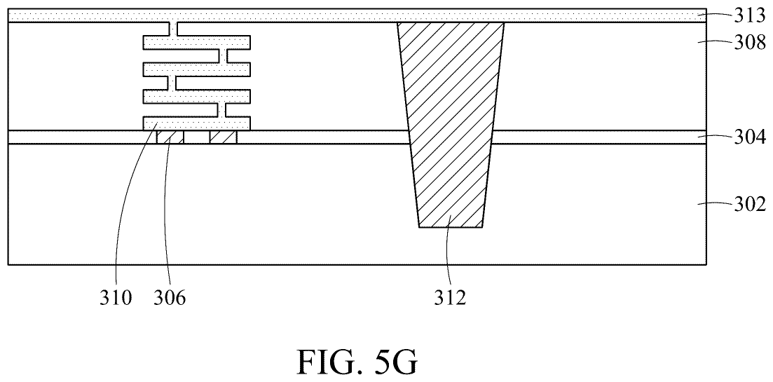

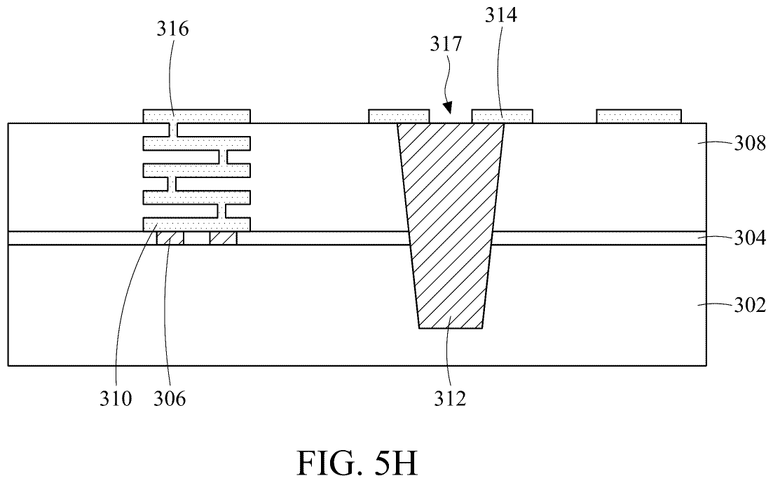

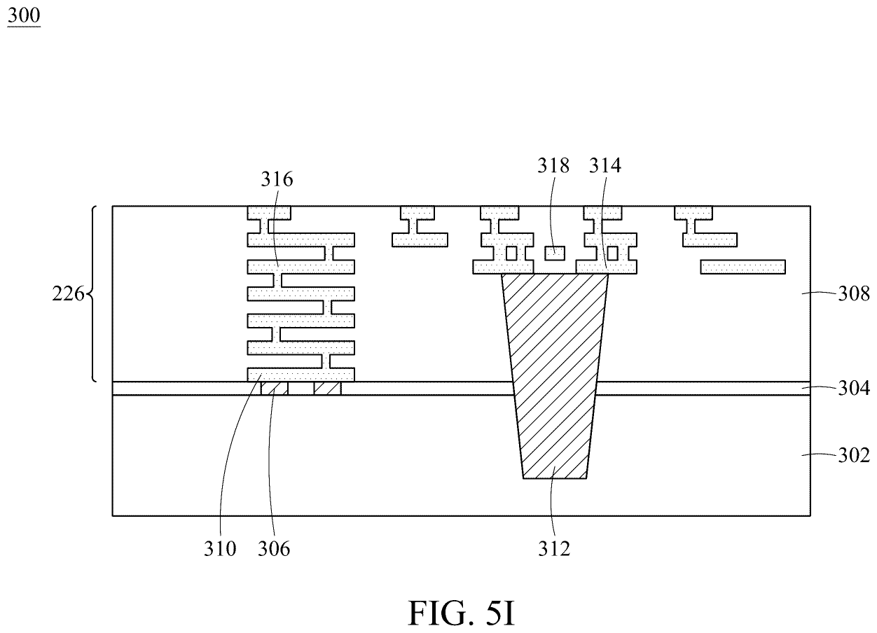

FIG. 5A to FIG. 5I are schematic views of a forming a semiconductor device 300, in accordance with some embodiments. As shown in FIG. 5A, a device substrate 302 is provided in some embodiments. The device substrate 302 may be similar to the device substrate 102, and it is not described again for simplicity. Subsequentially, as shown in FIG. 5B, an etch stop layer 304 and a conductive feature 306 are formed over the device substrate 302, in accordance with some embodiments. The material and process of the etch stop layer 304 and the conductive feature 306 may be similar to that of the etch stop layer 204 and the conductive feature 206.

In some embodiments, as shown in FIG. 5C, a dielectric layer 308 and conductive features 310 may be formed over the etch stop layer 304. The conductive features 310 may be electrically connected to the conductive feature 306 and formed in the dielectric layer 308, in accordance with some embodiments. The dielectric layer 308 may include several sub-layers. In some embodiments, the dielectric layer 308 may be referred to as intermetal dielectric (IMD) layers and may include silicon oxide or a low-k dielectric material whose k-value (dielectric constant) is smaller than that of silicon oxide, which is about 3.9, in accordance with some embodiments. In some embodiments, the low-k dielectric material includes a porous organosilicate thin film such as SiOCH, tetraethylorthosilicate (TEOS) oxide, undoped silicate glass, doped silicon oxide such as borophosphosilicate glass (BPSG), fused silica glass (FSG), phosphosilicate glass (PSG), fluorine-doped silicon dioxide, carbon-doped silicon dioxide, porous silicon dioxide, porous carbon-doped silicon dioxide, silicon carbon nitride (SiCN), silicon oxycarbide (SiOCN), spin-on silicon based polymeric dielectrics, or combinations thereof, in accordance with some embodiments.

As shown in FIG. 5D, an opening 311 is formed in the device substrate 302, the etching stop layer 304, and the dielectric layer 308, in accordance with some embodiments. In some embodiments, forming the opening 311 includes forming a patterned mask layer having an opening exposing a portion of the dielectric layer 308, and etching the device substrate 302, the etching stop layer 304, and the dielectric layer 308 using the patterned mask layer as an etch mask. The etching may be a dry etching process, a wet etching process, other etching process, or a combination thereof, in accordance with some embodiments.

In FIG. 5E, a conductive layer 313 is formed over the dielectric layer 308 and in the opening 311. In FIG. 5F, the conductive layer 313 is thinned to expose the dielectric layer 308 and the conductive feature 310. The conductive layer 313 remained in the opening 311 forms a via 312, in accordance with some embodiments. In FIG. 5G, a conductive layer 313 is formed over the dielectric layer 308, the conductive feature 310, and the via 312. In some embodiments, the thickness of the conductive layer 313 may be between about 200 nm and about 10 um.

In FIG. 5H, the conductive layer 313 is patterned to form a conductive feature 314 over the via 312 and a conductive feature 316 electrically connected to the conductive feature 310. An opening 317 is formed in the conductive feature 314, and a portion of the via 312 is exposed from the opening 317, in accordance with some embodiments. Such configuration reduces the thermal conduction through the conductive feature 314 to the via 312, thereby reducing the thermal expansion effect of the via 312 to enhance the reliability of the structure.

In FIG. 5I, more dielectric layers and conductive features are formed over the dielectric layer 308 to form the semiconductor device 300. In particular, a dielectric layer 320 includes the aforementioned dielectric layer 308 and other dielectric layers over the dielectric layer 308. In some embodiments, a feature 318 is formed right over the via 312. In some embodiments, the feature 318 may be a conductive feature electrically connected to the via 312 and conductive feature 314. In some embodiments, the feature 318 may be a dummy feature electrically isolated from the via 312 and the conductive features 314, and may be used for enhancing structural uniformity.

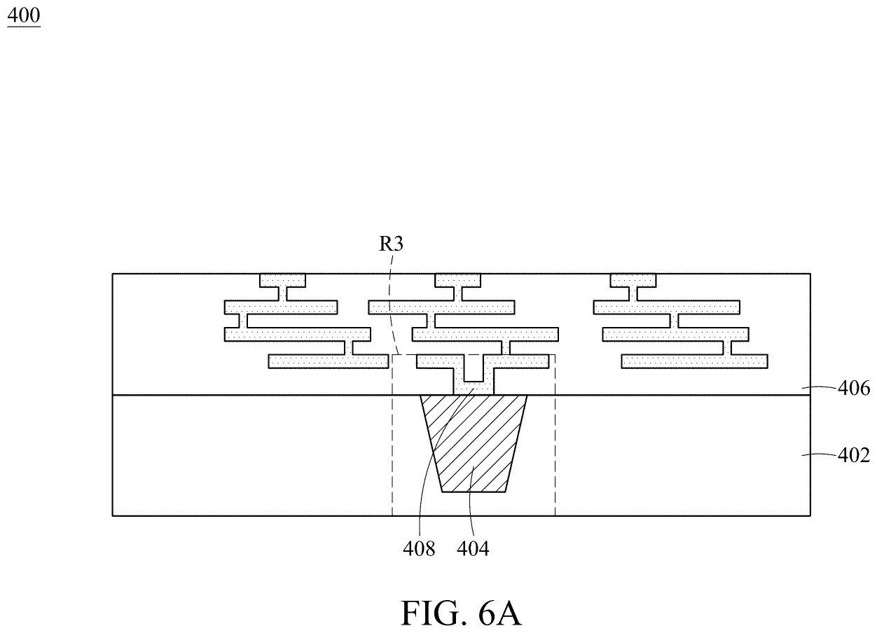

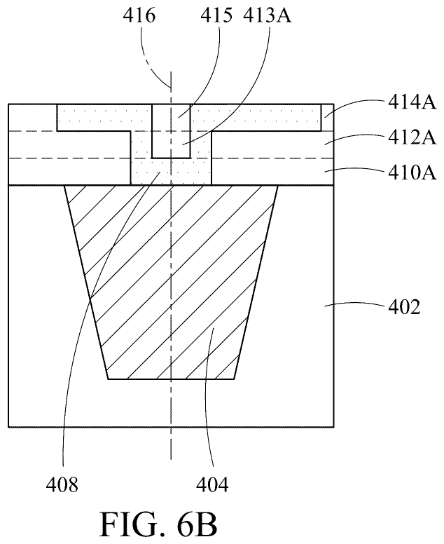

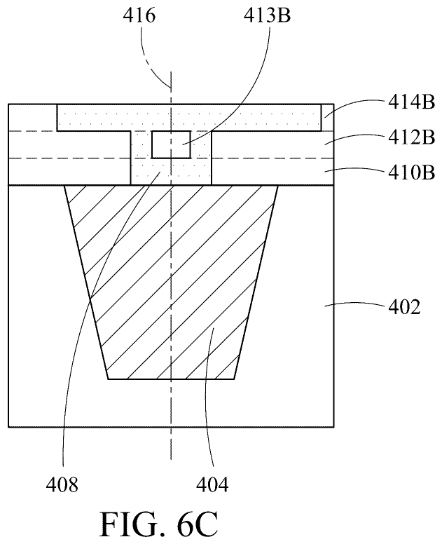

FIG. 6A is a cross-sectional view of a semiconductor device 400, in accordance with some embodiments. As shown in FIG. 6A, the semiconductor device 400 includes a device substrate 402, a via 404 formed in the device substrate 402, a dielectric layer 406 dispose over the device substrate 402, and conductive features 408 formed in the dielectric layer 406 and electrically connected to the via 404, in accordance with some embodiments.

FIG. 6B is an enlarged view of a region R3 in FIG. 6A, in accordance with some embodiments. As shown in FIG. 6B, the dielectric layer 406 may include several sub-layers 410A, 412A, and 414A, and the conductive features 408 may be formed therein, in accordance with some embodiments. In some embodiments, a top surface of the via 404 is in contact with the conductive features 408 and the sub-layer 410A of the dielectric layer 406. In some embodiments, a portion of the sub-layer 412A surrounded by the conductive features 408 may be annotated as a dielectric feature 413A. In some embodiments, a portion of the sub-layer 414A surrounded by the conductive features 408 may be annotated as a dielectric feature 415. In some embodiments, a central axis 416 of the via 404 may pass through the conductive features 408, the dielectric feature 413A, and the dielectric feature 415.

FIG. 6C is an enlarged view showing another configuration of the region R3 in FIG. 6A, in accordance with other embodiments. As shown in FIG. 6C, the dielectric layer 406 may include several sub-layers 410B, 412B, and 414B, and the conductive features 408 may be formed therein, in accordance with some embodiments. In some embodiments, a top surface of the via 404 is in contact with the conductive features 408 and the sub-layer 410B of the dielectric layer 406. In some embodiments, a portion of the sub-layer 412B surrounded by the conductive features 408 may be annotated as a dielectric feature 413B. In some embodiments, a central axis 416 of the via 404 may pass through the conductive features 408 and the dielectric feature 413B. In some embodiments, the dielectric feature 413B may be sandwiched by the conductive features 408 along the central axis 416.

In summary, semiconductor devices and methods for forming thereof are provided in some embodiments of the present disclosure. Such configuration forms an opening when forming the conductive feature over the via to expose a portion of the via, and then dielectric material is filled into the opening to reduce the heat conduction on the features over the via. Therefore, via protrusion during subsequent thermal process is mitigated to enhance process reliability.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

A semiconductor device is provided in some embodiments of the present disclosure. The semiconductor device includes a device substrate, a via formed in the device substrate, a conductive feature partially covering a top surface of the via, and a dielectric layer disposed over the device substrate and extending into the conductive feature, wherein the dielectric layer is in contact with between 5% and 95% of the top surface of the via.

A semiconductor device is provided in some embodiments of the present disclosure. The semiconductor device includes a device substrate, a via formed in the device substrate, a dielectric layer formed over the via and covering a first area of a top surface of the via, and a conductive feature formed over the via and covering a second area of the top surface, wherein the second area is adjacent to the first area.

A method for forming a semiconductor device is provided in some embodiments of the present disclosure. The method includes providing a device substrate, forming a via in the device substrate, forming a conductive feature over the via, wherein the conductive feature comprises an opening, and a top surface of the via is exposed from the opening, and forming a first dielectric layer over the via and the conductive feature, wherein the first dielectric layer is formed in the opening and in contact with the top surface of the via.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a device substrate;
a via formed in the device substrate;
a conductive feature partially covering a top surface of the via; and
a dielectric layer disposed over the device substrate and extending into the conductive feature, wherein the dielectric layer is in contact with between 5% and 95% of a top surface of the via.

2. The semiconductor device as claimed in claim 1, wherein the conductive feature has a meshed structure in a top view.

3. The semiconductor device as claimed in claim 2, wherein the conductive feature overlaps an edge of the via.

4. The semiconductor device as claimed in claim 2, wherein the conductive feature is enclosed with an edge of the via.

5. The semiconductor device as claimed in claim 1, wherein the conductive feature comprises a plurality of strip-shaped portions extending in an identical direction.

6. The semiconductor device as claimed in claim 5, wherein the strip-shaped portions are enclosed within an edge of the via in a top view.

7. The semiconductor device as claimed in claim 5, wherein the strip-shaped portions extend beyond an edge of the via in a top view.

8. A semiconductor device, comprising:
a device substrate;
a via formed in the device substrate;
a dielectric layer formed over the via and covering a first area of a top surface of the via; and
a conductive feature formed over the via and covering a second area of the top surface, wherein the second area is adjacent to the first area.

9. The semiconductor device as claimed in claim 8, wherein the first area is surrounded by the second area.

10. The semiconductor device as claimed in claim 9, further comprising a first auxiliary feature formed over the via and covering a third area, wherein the third area is surrounded by the first area.

11. The semiconductor device as claimed in claim 8, further comprising a second auxiliary feature formed over the device substrate in a fourth area, wherein the second auxiliary feature is spaced apart from the via in a top view.

12. The semiconductor device as claimed in claim 8, further comprising a third auxiliary feature formed over the device substrate in a fifth area, wherein the fifth area covers an edge of the via.

13. The semiconductor device as claimed in claim 8, wherein the conductive feature extends from the via beyond and edge of the via to the device substrate in a top view.

14. The semiconductor device as claimed in claim 8, wherein the second area is tangent to an edge of the via in a top view.

15. A method for forming a semiconductor device, comprising:
providing a device substrate;
forming a via in the device substrate;
forming a conductive feature over the via, wherein the conductive feature comprises an opening, and a top surface of the via is exposed from the opening; and
forming a first dielectric layer over the via and the conductive feature, wherein the first dielectric layer is formed in the opening and in contact with the top surface of the via.

16. The method as claimed in claim 15, further comprising forming an etch stop layer over the device substrate, wherein the via penetrates the etch stop layer.

17. The method as claimed in claim 16, wherein the conductive feature is formed over the etch stop layer.

18. The method as claimed in claim 15, further comprising forming a second dielectric layer over the device substrate, wherein the via is further formed in the second dielectric layer.

19. The method as claimed in claim 15, further comprising forming a dummy feature over the via, wherein the dummy feature is electrically isolated from the via.

20. The method as claimed in claim 19, wherein the dummy feature overlaps an edge of the via in a top view.
